(19) United States
(12) Patent Application Publication
(10) Pub. No.: US 2009/0320898 A1
(43) Pub. Date: Dec. 31, 2009

(54) Configurable Articulated Photovoltaic Assembly

(76) Inventor: Michael L. Gumm, Santa Cruz, CA (US)

Correspondence Address: PATWRITE LLC, 408 W. MAIN ST., MARSHALLTOWN, IA, 50158-5759, US

(21) Appl. No.: 12/552,131

(22) Filed: Sep. 1, 2009

Related U.S. Application Data
(63) Continuation-in-part of application No. 12/352,605, filed on Jan. 12, 2009.
(60) Provisional application No. 61/010,464, filed on Jan. 10, 2008.

(51) Int. Cl. H01L 31/045

(52) U.S. Cl. 136/245

(57) ABSTRACT

A configurable articulated photovoltaic assembly has a plurality of photovoltaic modules hingedly connected to each other to allow the assembly to fold for transportation. The assembly is unfolded at the installation site, positioned and secured in place using adhesives, mechanical fasteners or both. The angle of the solar panels may be adjusted by moving support panels from horizontal to vertical. Once secured, the panels are rigidly held in place and are integrated with the building surface such as a roof or wall. Hinges are bidirectional and include metal, fabric and sliding extension types. Each module is wired and connected to a junction box attached therein.

### CROSS REFERENCE TO RELATED APPLICATIONS

This is a continuation in part of U.S. patent application Ser. No. 12/352,605, filed Jan. 12, 2009, which in turn claims priority to Provisional Application No. 61/010,464000, filed on Jan. 10, 2008 the complete disclosures of each of which are hereby incorporated by reference.

### BACKGROUND OF THE INVENTION

The present invention is a new multiple configurable articulating photovoltaic assembly and installation method(s) created by combining photovoltaic modules together, connecting individual photovoltaic panel units together with any type of folding, movable, swinging or flexible articulated joint(s) for both horizontal and vertical placement on a building surface or construction substrate. The combination of configurable articulated photovoltaic assemblies and attachment method results in a self-contained solar array that is highly customizable and allows for optimal positioning of the arrays with respect to the impinging solar radiation.

In one configuration, the rigid photovoltaic solar enabled panels can be combined with other non-solar rigid panel components using any type articulating joint(s) composed of either flexible membranes, textiles or pivoting, swinging, sliding hinges to form a self-contained foldable photovoltaic module array for ease of product assemble, shipping and installation and can be applied to a building surface once configured into any number geometrical forms.

The assembled invention, folded for ease of packaging and shipping is delivered to the project site where the solar module array can be unfolded into different construction configurations and installed over a broad range of building and construction surfaces, including roofs, metal, walls and concrete. Once secured, the assembly is integrated with the building surface to provide a very rigid and strong assembly.

### SUMMARY OF THE INVENTION

A configurable articulated photovoltaic assembly has a plurality of photovoltaic modules hingedly connected to each other to allow the assembly to fold for transportation. The assembly is unfolded at the installation site, positioned and secured in place using adhesives, mechanical fasteners or both. The angle of the solar panels may be adjusted by moving support panels from horizontal to vertical. Once secured, the panels are rigidly held in place and are integrated with the building surface such as a roof or wall. Hinges are bidirectional and include metal, fabric and sliding extension types. Each module is wired and connected to a junction box attached therein.

Other features and advantages of the instant invention will become apparent from the following description of the invention which refers to the accompanying drawings.

### BRIEF DESCRIPTION OF THE DRAWINGS

FIG. 1 is a perspective drawing of a configurable articulated photovoltaic assembly according to an embodiment of the invention.

FIG. 2 is a perspective drawing of the configurable articulated photovoltaic assembly shown in FIG. 1.

FIG. 3 is a perspective drawing of the configurable articulated photovoltaic assembly shown in FIG. 1.

FIG. 4 is a perspective drawing of the configurable articulated photovoltaic assembly shown in FIG. 1.

FIG. 5 is a side view of the configurable articulated photovoltaic assembly shown in FIG. 1.

FIG. 6 is a close up of the section shown in FIG. 5.

FIG. 7 is a side view of the configurable articulated photovoltaic assembly shown in FIG. 1 in a folded position.

FIG. 8 is a perspective drawing of a configurable articulated photovoltaic assembly according to an embodiment of the invention.

FIG. 9 is a side view of the configurable articulated photovoltaic assembly shown in FIG. 8 in a folded position.

FIG. 10 is a perspective drawing of the configurable articulated photovoltaic assembly shown in FIG. 9.

FIG. 11 is a perspective drawing of a configurable articulated photovoltaic assembly according to an embodiment of the invention.

FIG. 12 is a side view of an attachment means according to an embodiment of the invention.

FIG. 13 is a side view of an attachment means according to an embodiment of the invention.

FIG. 14 is a side view of an attachment means according to an embodiment of the invention.

FIG. 15 is a side view of an attachment means according to an embodiment of the invention.

FIG. 16 is a side view of an attachment means according to an embodiment of the invention.

FIG. 17 is a side cut-away view of an attachment means according to an embodiment of the invention.

FIG. 18 is a side view of an attachment means according to an embodiment of the invention.

FIG. 19 is a side cut-away view of an attachment means according to an embodiment of the invention.

FIG. 20 is a detailed perspective view of an attachment means according to an embodiment of the invention.

FIG. 21 is a side view of a configurable articulated photovoltaic assembly according to an embodiment of the present invention.

FIG. 22 is a side view of a configurable articulated photovoltaic assembly according to an embodiment of the present invention.

FIG. 23 is a side view of a configurable articulated photovoltaic assembly according to an embodiment of the present invention.

FIG. 24 is a side view of a configurable articulated photovoltaic assembly according to an embodiment of the present invention.

### DETAILED DESCRIPTION OF THE INVENTION

In the following detailed description of the invention, reference is made to the drawings in which reference numerals refer to like elements, and which are intended to show by way of illustration specific embodiments in which the invention may be practiced. It is understood that other embodiments may be utilized and that structural changes may be made without departing from the scope and spirit of the invention.

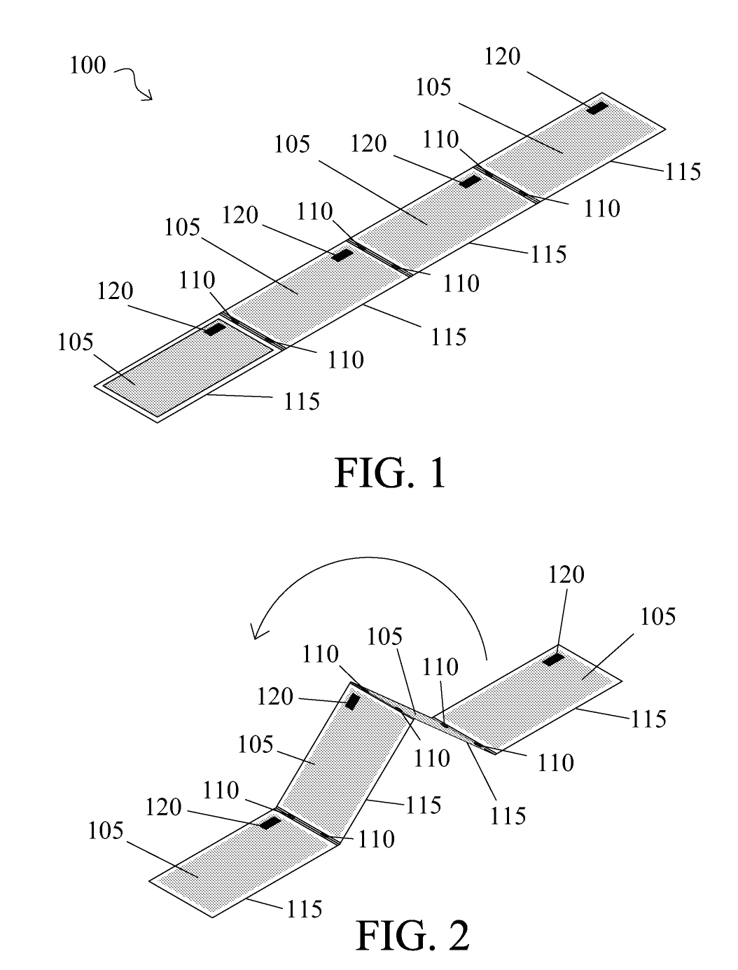

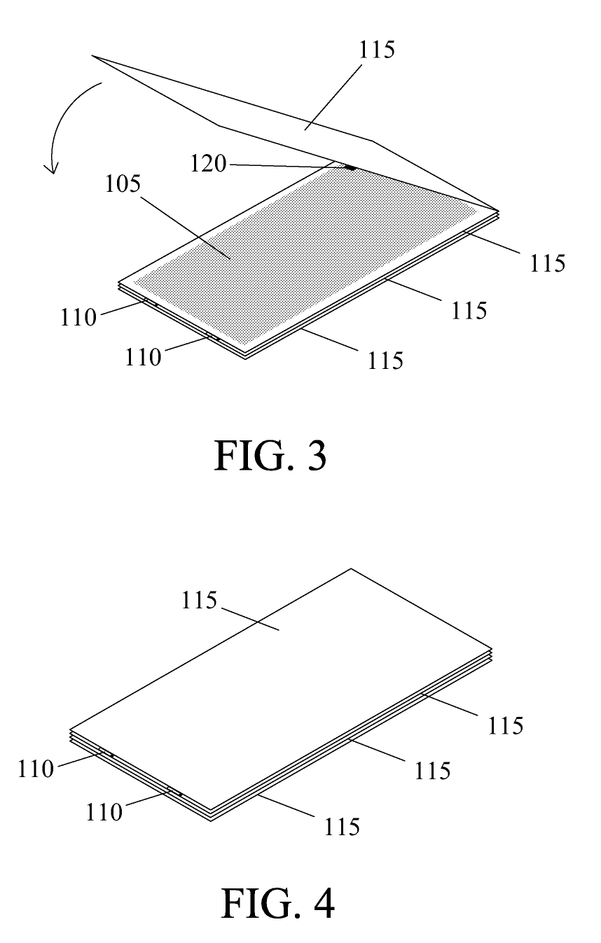

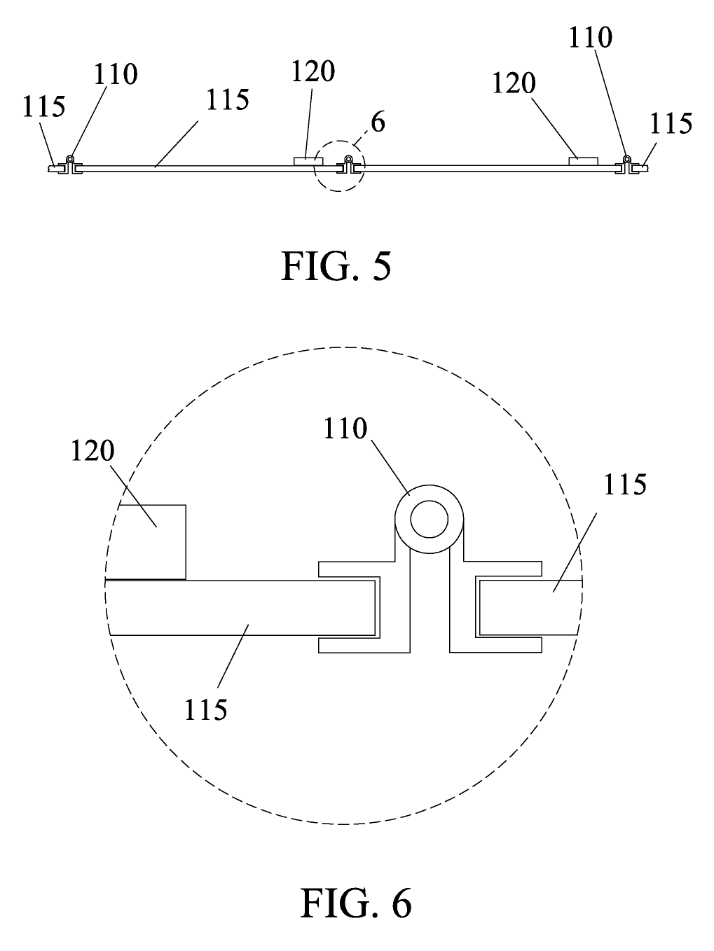

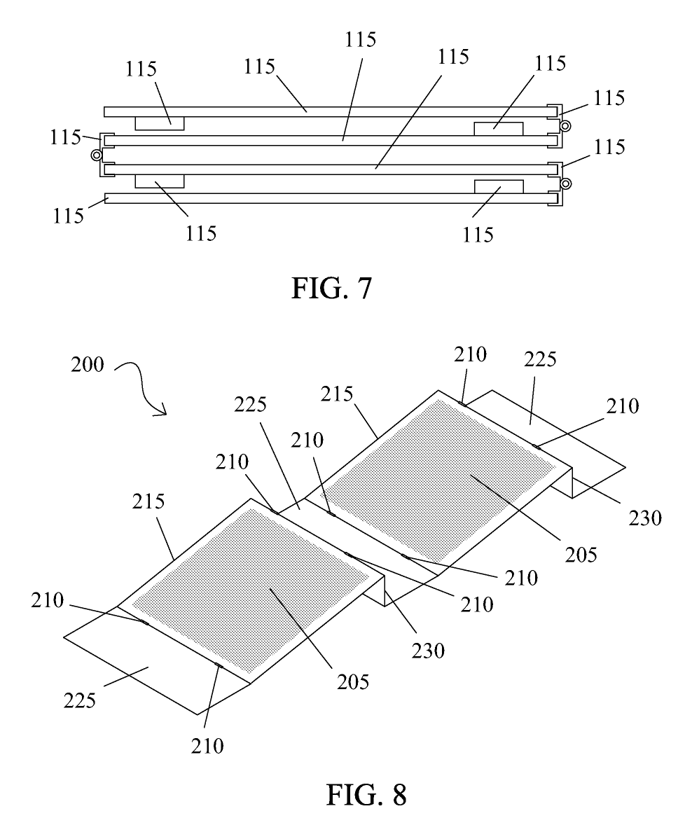

Referring to FIGS. 1 through 7, a configurable articulated photovoltaic assembly 100 comprises a plurality of photovoltaic modules 105 being attached to a support substrate 115 which can be made of glass or non glass materials including metal, polymers, composites, etc. that add to the structural integrity of the modules 105. A plurality of hinge members 110 join each module 105 allowing articulation. A plurality of junction boxes 120 are used to provide electrical communication and control of each module 105. Hinge members 110 allow modules 105 to fold relatively flat for ease in transportation and storage when not in use.

Now referring to FIGS. 8 and 9, a configurable articulated photovoltaic assembly 200 comprises a plurality of photovoltaic modules 205 being attached to a support substrate 215 which as discussed above, can be made of glass or non glass materials including metal, polymers, composites, etc. that add to the structural integrity of the modules 205.

A plurality of base attachment plates 225 are attached to one end of modules 205. A plurality of risers 230 are hingedly attached to one end of module 205 and to an end of base attachment plates 225. This allows configurable articulated photovoltaic assembly 200 to fold generally flat when not in use and to be positioned at a selected angle (90 degrees in figures) to optimize their efficiency.

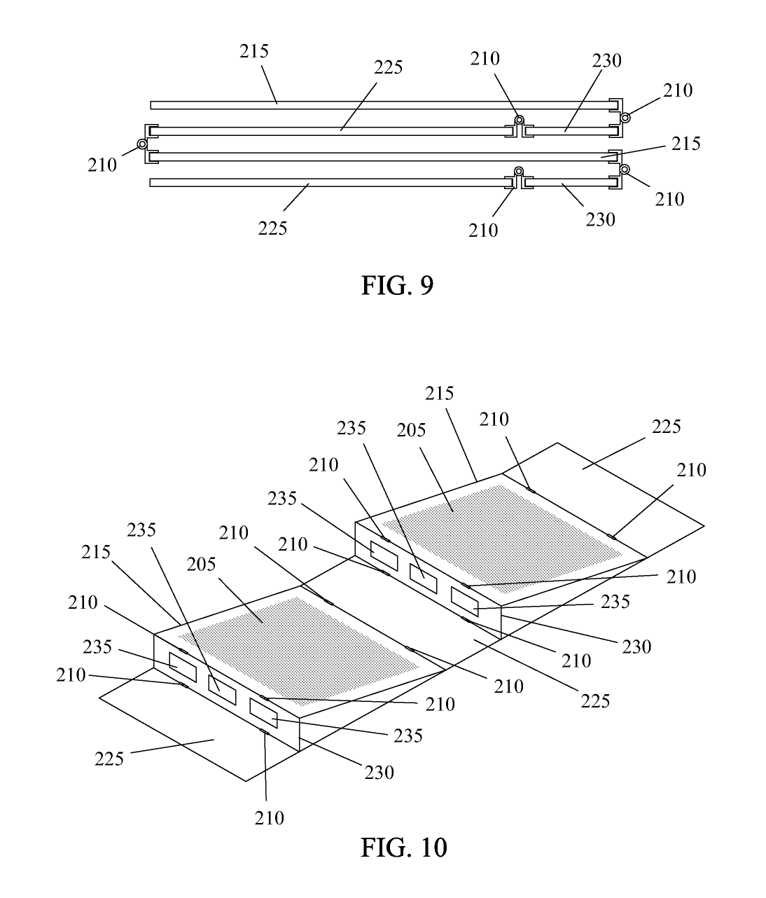

FIG. 10 shows the addition of a plurality of ventilation openings 235 which allow air flow beneath modules 205 to increase efficiency and to decrease heat transfer from modules 205 and a structure (not shown).

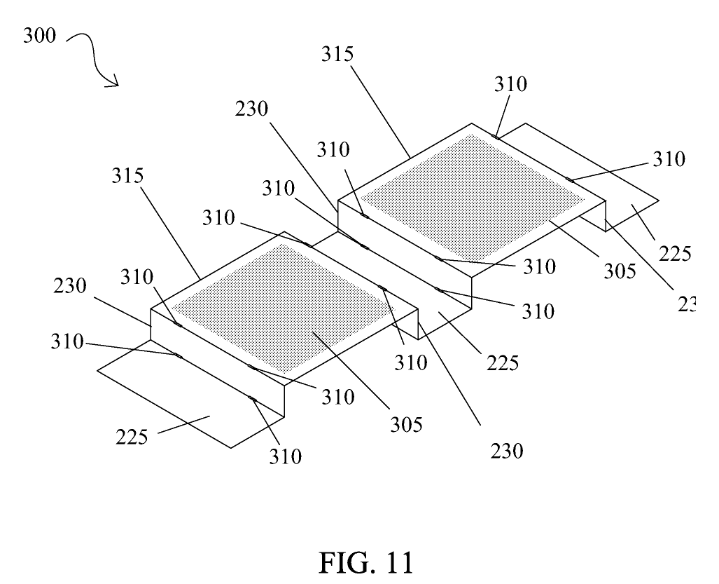

Now referring to FIG. 11, a configurable articulated photovoltaic assembly 300 comprises a plurality of photovoltaic modules 305 being attached to a support substrate 315 which as discussed above, can be made of glass or non glass materials including metal, polymers, composites, etc. that add to the structural integrity of the modules 305.

A plurality of base attachment plates 325 are attached to one end of modules 305. A plurality of risers 330 are hingedly attached to one end of module 305 and to an end of base attachment plates 325. This allows configurable articulated photovoltaic assembly 300 to fold generally flat when not in use and to be positioned with channels formed between modules 305.

The new invention is composed of a rigid panel is made from a number of different materials and components laminated together and integrated to form a lightweight rigid panel with very low deflection and torsion characteristics. One or more flexible thin polymer or metal films creating a module back sheets are laminated onto the panel to create the back laminated substrate assemble for a photovoltaic module. An a-Si, CIGS, or CdTe thin film photovoltaic material with optional polymer encapsulating films depending the solar material design and technology is laminated onto the back surface back sheet laminate.

The top of the photovoltaic carrier surface is covered and sealed by one or more layers of polymers that are solar transparent. Individual covering layers are chosen and layered in different combinations depending on the physical and chemical performance of each polymer. These covering materials can be moisture resistant, UV resistant polymer(s) and flexible, semi-flexible or rigid and any thickness depending on the performance characteristics and specifications of the PV module. Other transparent materials including glass and solid plastics can be integrated into the layers of polymers. The ability to use multi-layers of covering materials and indifferent thickness creates a number of new module design options.

The top surface covering material layer can be specified to have very strong UV resistance and good resistance to external environmental conditions and events. The inter-ply materials can have low UV resistance, but exhibit extremely strong hydrophobic characteristics and is protected from UV degradation by the top protective layer(s) that may have poor hydrophobic performance.

Other layers including thin a Fresnel lens in the panel helps to concentrate light to increase power performance. In addition to the thin film photovoltaic material, single or multi-crystalline silicon can be laminated onto the panel surface in-place of or with the thin film photovoltaic materials.

It is possible to use a one layer transparent polymer with a CIGS, A-Si or CdTe or solar active material in the module assembly and under this layer place another solar active material either thin film materials or crystalline silicon. The lower layer can absorb solar energy at different wavelengths and frequencies not absorbed by the higher placed transparent solar active polymer making effective use of a broader spectrum range of solar energy from the sun.

The invention makes use of rigid photovoltaic panels as a stand-alone PV module and can be installed using the many application methods described within this document. The invention also consists of these PV module panels linked or joined together using flexible joint materials, pivots or any type of hinged or swing joint that is suitable to join and link the panels to form a multi-unit panel PV module array. The multi-panel PV array can be folded up at the factory for easy shipment to the project where the module is unfolded and installed at the project using new application techniques designed specifically for this new module design or the different application technologies described within this document and applied to any building and construction surface(s). The same assembly and panel connection methods and technologies can be used with rigid silicon photovoltaic cells, including glass modules and glass hybrid modules and laminated polymer modules.

These new “fan-fold” modules can be applied to any sloped, horizontal or vertical surfaces. By connecting different types of non-solar active panels in-between, the solar active modules (panels) form a new transportable, foldable rack array system can be created on site without using standard rack array components. This new fan folded module array can be integrated onto any roof membrane systems and over metal roof surfaces, concrete and wall surfaces. These panels can be applied directly to any vertical, sloped or horizontal surface. By combining different interconnecting panels using the same flexible or hinged joint systems, different arrays can be created for different construction or building surfaces either as a single unit or in multi-unit configurations forming self-contained sloped (slanted) arrays or set up upon two equal sized non-solar panels to create an array raised off the application surface. With set module lengths, wiring is highly simplified and can be daisy chained together.

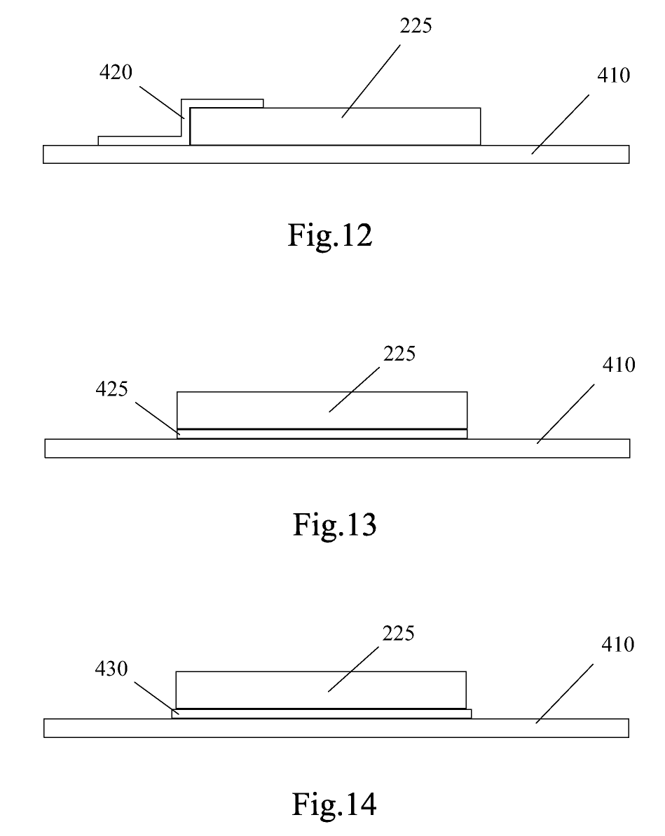

Referring to FIG. 12, an attachment method for attaching a fan-fold solar module 225 is shown using a flashing membrane 420. Flashing membrane 420 may be a thermoplastic roofing membrane such as PVC, TPO or a suitable thermoset elastomeric roofing membrane. Examples of suitable membranes include such materials as EPDM (ethylene Propylene Diene Monomer) or Hypalon® (Chlorosulfinated polyethylene synthetic rubber). Flashing membrane 420 is attached to solar module 225 using a one or two-part contact pressure adhesive (not shown) applied between a building surface 410 and membrane 420 and between membrane 420 and solar module 225. Examples of suitable membranes include adhesives, tapes chemical or hot air welding, etc.

Referring now to FIG. 13, an attachment method for attaching a fan-fold solar module 225 is shown using a pressure sensitive adhesive 425 applied between solar module 225 and building surface 410. Pressure sensitive adhesive 425 may be applied at the factory with a release covering that is removed during installation or may be applied on site.

Now referring to FIG. 14, an attachment method for attaching a fan-fold solar module 225 is shown using an adhesive 430 applied between solar module 225 and building surface 410. Examples of adhesives include construction adhesives and sealants, hot melt thermoset adhesives, hot asphalts or cold process adhesives. Suitable adhesives also include polymer/solvent based one or two part contact adhesives depending on the particular application requirements.

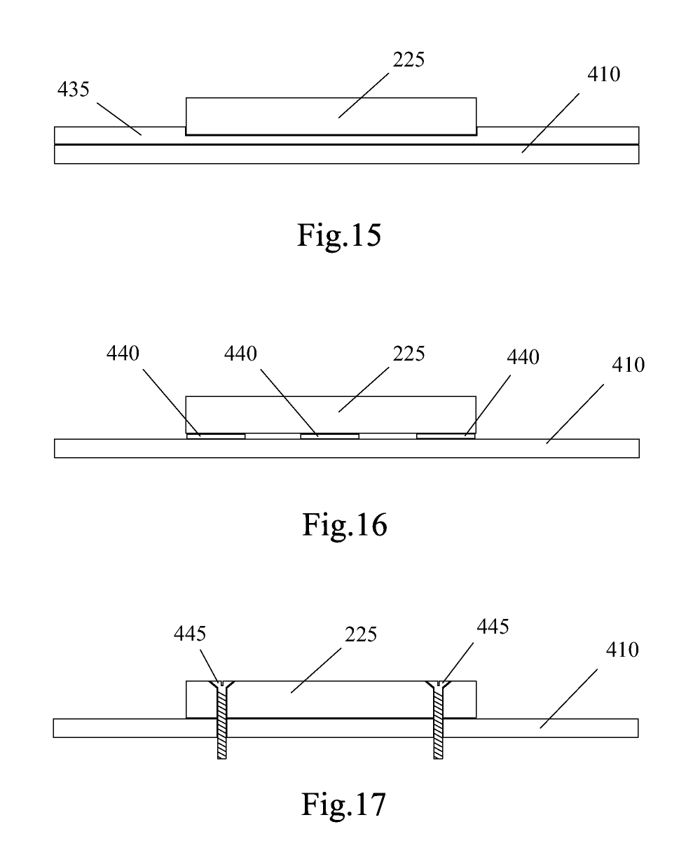

Referring now to FIG. 15, an attachment method for attaching a fan-fold solar module 225 is shown using a layer of elastomeric coating 435 to adhere solar module 225 and to protect building surface 410. The type of elastomeric coating used depends on the selected application.

FIG. 16 shows an attachment method for attaching a fan-fold solar module 225 that utilizes pressure sensitive construction tape 440 to adhere solar module 225 to building surface 410. As discussed above, tape 440 may be factory applied with a release layer that is peeled off during installation.

Referring to FIG. 17, an attachment method for attaching a fan-fold solar module 225 is shown using a mechanical fastener or fasteners 445. Of course it is possible to combine two or more of these methods together to provide attachment in a variety of installation conditions.

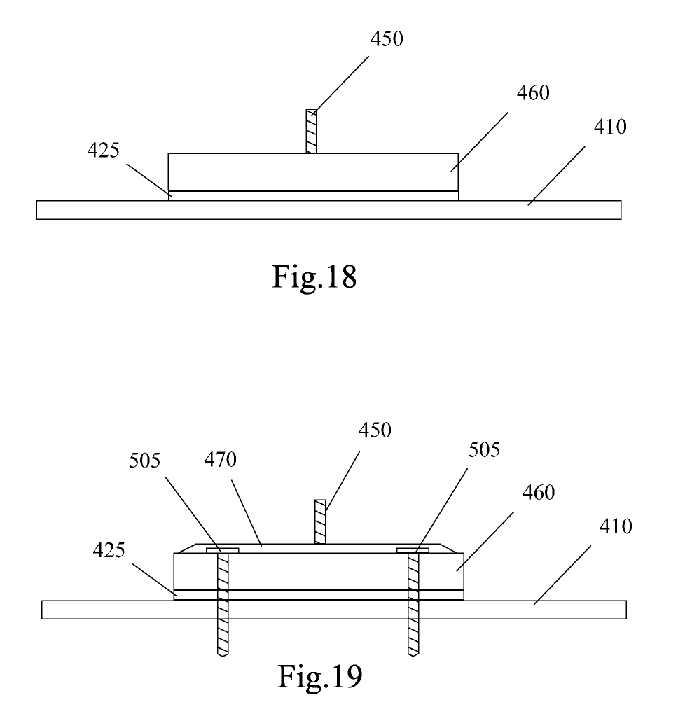

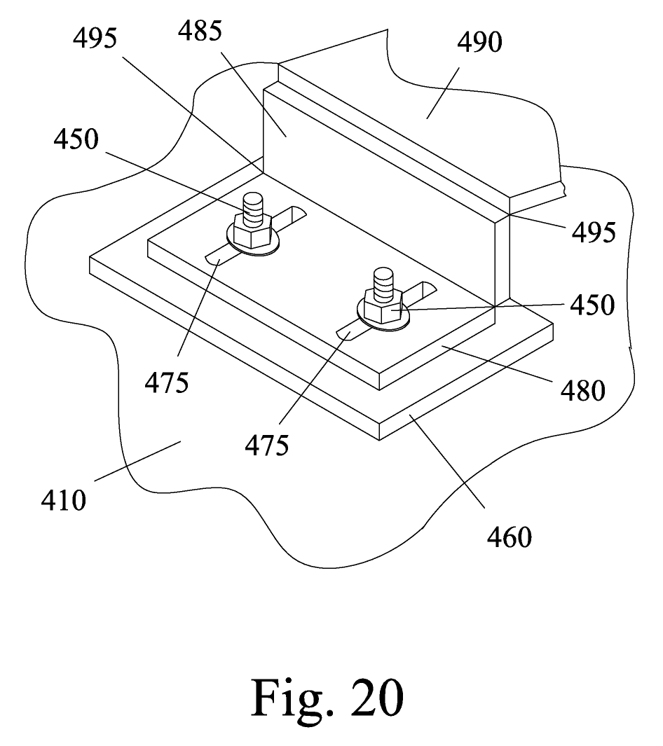

Referring to FIGS. 18, 19 and 20, a support base panel 460 is secured to building surface 410 using pressure sensitive adhesive 425. Mechanical fasteners are secured in a base attachment panel 460. Base attachment panel 460 may be secured to building surface 410 using adhesives 425, mechanical fasteners 505 or both. An articulated solar panel 490 is secured by tightening fasteners 450 which slide within slots 475 disposed in an attachment panel 480. Attachment panel 480 is hingedly attached to a support panel 485. Support panel 485 is hingedly attached to solar panel 490. An articulated hinge 495 is used to allow solar panel 490 to be positioned in the optimum orientation to provide maximum solar efficiency. Attachment panel 480 is also hingedly connected to support panel 485. Support panel may be positioned anywhere from vertical to horizontal. By adjusting the position of attachment panel 480, the angle of solar panel 490 is adjusted. Once mechanical fasteners 450 are tightened, the position of solar panel 490 is set.

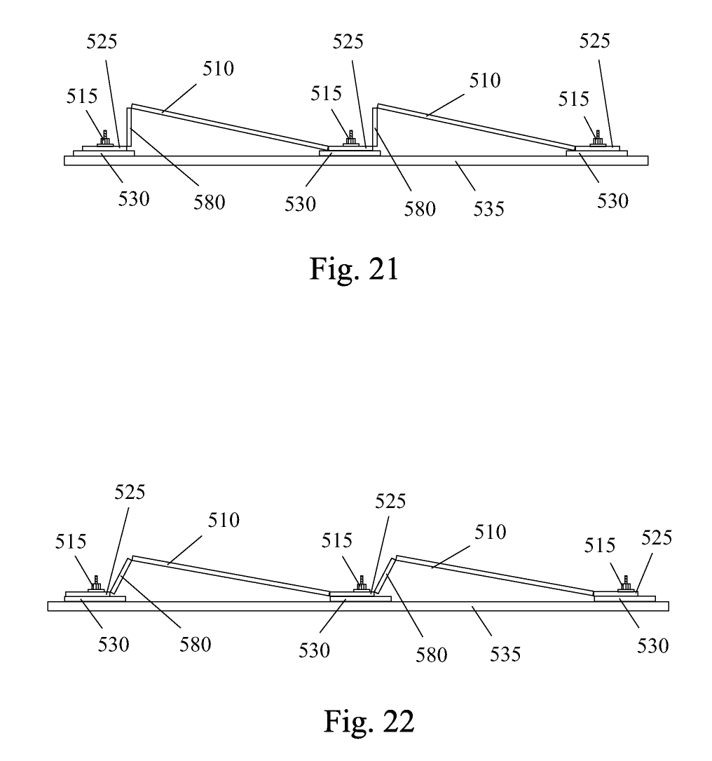

Now referring to FIGS. 21 and 22, articulated solar panels 510 are shown installed on a building surface 535 using a plurality of attachment panels 525, support base panels 530 and support panels 580. The angle that the solar panels 510 are placed can be altered by simply changing the position of the support base panels 530 and support panels 580 and tightening a plurality of mechanical fasteners 515.

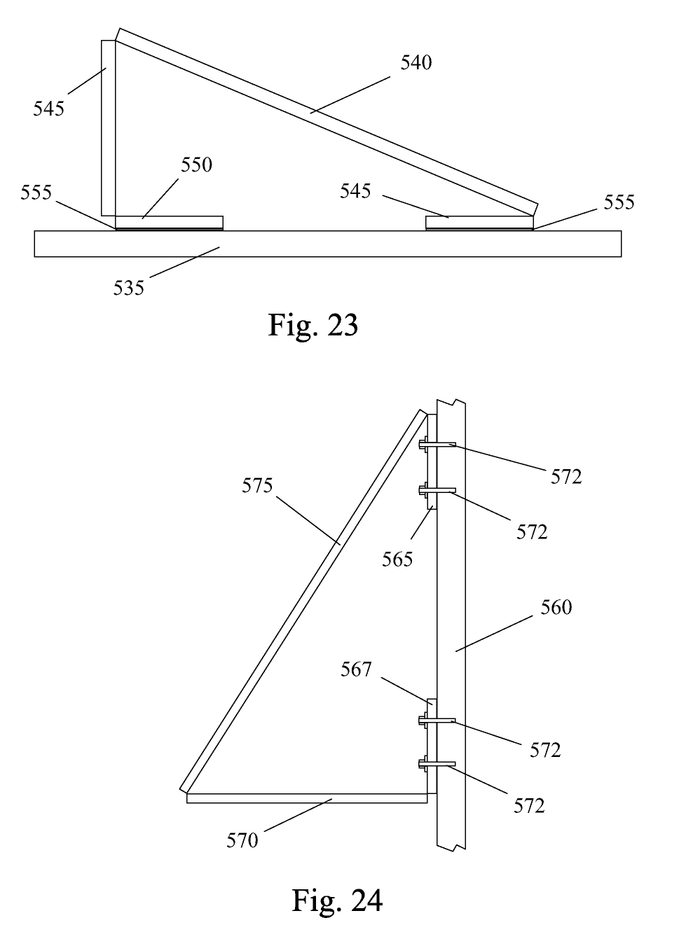

Referring to FIG. 23, an articulated solar assembly is shown being installed on a building surface such as a roof 535. A solar panel 540 is hingedly connected to a support panel 545 on one end and an attachment support panel 545 at the other. Support panel 540 is hingedly connected to another attachment support panel 550. An adhesive 555 is applied under attachment panels 545 and 550 respectively to secure the assembly to roof 535. As discussed above, adhesive 555 may be pressure sensitive tape or glue, rubber adhesive, one or two part adhesives, etc. Additionally, as discussed above, if adhesive 555 is applied at the factory, a release layer may be added to aid in installation.

Referring now to FIG. 24, an articulated solar assembly is shown vertically mounted to a building surface 560. A solar panel 575 is hingedly attached to an attachment panel 565 on one end and a support panel 570 at the other end. Support panel 570 is hingedly attached to another attachment panel 567. The attachment panels 565 and 567 are attached to building surface 560 with mechanical fasteners 572.

In use, the articulated solar assembly can be removed from the box and easily installed, unfolded, adjusted to a particular solar angle and then attaching to the surface such as a roof or wall. This simple assembly is easily installed without additional hardware required nor surface penetration. This allows the solar panels to be quickly installed.

The configurable articulated photovoltaic assembly is constructed of rigid composite panels that are laminated together to form an integrated lightweight panel with very little deflection and torsion. The panels are composed of metal and polymers. Of course, the panels may be constructed of a single material like plastic as long as the deflection and torsion characteristics are suitable for exterior mounting. Additionally, the panels may be composed of a solid or sandwich construction of metal and polymer layers or with an open corrugated core with metal layers on the exterior surface.

The photovoltaic modules may be conventional crystalline silicon or a thin film solar material with a glass top surface which protects the panel from the elements. In one embodiment, the photovoltaic modules are composed of crystalline silicon which protects the solar materials from the elements. In another embodiment, the photovoltaic modules are composed of thin film solar materials encapsulated within a polymer for protection. The polymer-encapsulated solar cells are bonded to the rigid composite panel. Again the materials are chosen to provide a rigid structure with minimum torsion and deflection.

Although the instant invention has been described in relation to particular embodiments thereof, many other variations and modifications and other uses will become apparent to those skilled in the art.

What is claimed is:

1. A configurable articulated photovoltaic assembly comprises:
at least two photovoltaic modules hingedly connected together; and
an attachment means for adjustably attaching said at least two photovoltaic modules to a surface.

2. The configurable articulated photovoltaic assembly according to claim 1 wherein said attachment means comprises a base attachment plate adjustably attached to an end of each one of said at least two photovoltaic modules and a riser hingedly attached to an opposite end of each one of said at least two photovoltaic modules.

3. The configurable articulated photovoltaic assembly according to claim 2 further comprising at least one mechanical fastener for attaching said base attachment plate to said surface.

4. The configurable articulated photovoltaic assembly according to claim 2 further comprising at least one adhesive fastener for attaching said base attachment plate to said surface.

5. The configurable articulated photovoltaic assembly according to claim 3 wherein said base attachment plate has at least one elongated adjustment slot wherein said at least one mechanical fastener is movably constrained within said elongated adjustment slot.

6. The configurable articulated photovoltaic assembly according to claim 2 further comprising an electrical control circuit electrically connected to said configurable articulated photovoltaic assembly wherein energy produced by said at least two photovoltaic modules is regulated.

7. The configurable articulated photovoltaic assembly according to claim 2 further comprising at least one ventilation opening in said riser.

8. A method of installing a configurable photovoltaic assembly comprising the steps of:
obtaining a configurable articulated photovoltaic assembly comprising at least two photovoltaic modules hingedly connected together and an attachment means for adjustably attaching means for attaching said at least two photovoltaic modules to a surface;
selecting an operational angle for optimizing solar radiation impinging on said configurable articulated photovoltaic assembly;
securing said configurable articulated photovoltaic assembly to said surface using said attaching means wherein the position of each said at least two photovoltaic modules are optimized; and
electrically connecting said at configurable articulated photovoltaic assembly to a control circuit.

9. The method of installing a configurable articulated photovoltaic assembly according to claim 7 wherein the said surface is a vertical surface.
